(19) United States
(12) Patent Application Publication
(10) Pub. No.: US 2025/0024653 A1
(43) Pub. Date: Jan. 16, 2025

(54) VIBRATION ENHANCED CONVECTION HEAT TRANSFER IN A WEARABLE DEVICE

(71) Applicant: Meta Platforms Technologies, LLC, Menlo Park, CA (US)

(72) Inventors: Dusan COSO, Bothell, WA (US); Nagi ELABBASI, Southborough, MA (US); Hongtao GUO, Redmond, WA (US); Shenghui LEI, Castleknock (IE); Sadegh AGHAEI, Worcester, MA (US); Jonathan Robert PETERSON, Woodinville, WA (US)

(73) Assignee: Meta Platforms Technologies, LLC, Menlo Park, CA (US)

(21) Appl. No.: 18/351,807

(22) Filed: Jul. 13, 2023

(51) Int. Cl. H05K 7/20; G06F 1/16; G06F 1/20

(52) U.S. Cl. CPC H05K 7/20963; G06F 1/163; G06F 1/203; G06F 1/206

(57) ABSTRACT

An approach for heat management in wearable devices is provided. One or more vibration enhanced convection heat transfer surfaces may be incorporated to exterior surfaces of a wearable device. A controller may take into account ambient temperature, available power expected power consumption by the vibration enhanced convection heat transfer surface(s), and/or expected heat reduction, and activate the vibration enhanced convection heat transfer surface(s) to expel heat from the wearable device. Operational parameters of the vibration enhanced convection heat transfer surface(s) such as a frequency and/or an amplitude of vibration may also be determined and set based on the internal and external factors including a shape, a location, and/or a size of the vibration enhanced convection heat transfer surface(s).

### TECHNICAL FIELD

This patent application relates generally to wearable devices, and in particular, to vibration enhanced convection heat transfer in a wearable device.

### BACKGROUND

With recent advances in technology, prevalence and proliferation of content creation and delivery has increased greatly in recent years. In particular, interactive content such as virtual reality (VR) content, augmented reality (AR) content, mixed reality (MR) content, and content within and associated with a real and/or virtual environment (e.g., a “metaverse”) has become appealing to consumers.

Wearable devices, such as augmented reality (AR) eyewear or glasses, smartwatches, handheld controllers, and similar ones may include any number of electrical components. One challenge with such devices may involve heat management. Wearable device electronics may generate heat during operation. In addition, external environments such as body temperature of a person wearing the device and/or an ambient temperature may contribute to heating of the wearable device and/or limiting heat rejection pathways. To prevent undesirable operation or reduction of operational life of particular components in the wearable device, overheating needs to be avoided.

### BRIEF DESCRIPTION OF DRAWINGS

Features of the present disclosure are illustrated by way of example and not limited in the following figures, in which like numerals indicate like elements. One skilled in the art will readily recognize from the following that alternative examples of the structures and methods illustrated in the figures can be employed without departing from the principles described herein.

FIG. 1 illustrates a block diagram of an artificial reality system environment including a near-eye display, according to an example.

FIGS. 2A-2C illustrate various views of a near-eye display device including at least one heat rejection surface in the form of a head-mounted display (HMD) device, according to examples.

FIGS. 3A and 3B illustrate a perspective view and a top view of a near-eye display including at least one heat rejection surface in the form of a pair of glasses, according to an example.

FIG. 4 illustrates a smartwatch with at least one heat rejection surface, according to an example.

FIG. 5 illustrates a block diagram of major components and their interaction in a wearable device with heat management through vibration enhanced convection heat transfer, according to examples.

FIG. 6 illustrates various parameters in heat management through vibration enhanced convection heat transfer in a wearable device, according to examples.

FIG. 7 illustrates heat exchange with the environment for a vibrating heat rejection surface, according to an example.

FIGS. 8A and 8B illustrate heat transfer coefficient change for a vibrating heat rejection surface at different vibration frequency and amplitudes, according to examples.

FIG. 9 illustrates a flow diagram for a method of providing heat rejection through vibration enhanced convection heat transfer in a wearable device, according to some examples.

### DETAILED DESCRIPTION

For simplicity and illustrative purposes, the present application is described by referring mainly to examples thereof. In the following description, numerous specific details are set forth in order to provide a thorough understanding of the present application. It will be readily apparent, however, that the present application may be practiced without limitation to these specific details. In other instances, some methods and structures readily understood by one of ordinary skill in the art have not been described in detail so as not to unnecessarily obscure the present application. As used herein, the terms “a” and “an” are intended to denote at least one of a particular element, the term “includes” means includes but not limited to, the term “including” means including but not limited to, and the term “based on” means based at least in part on.

Wearable devices such as head-mounted display (HMD) devices, near-eye display devices, smart watches, handheld controllers, and similar ones are part of the metaverse, where interactive content such as virtual reality (VR) content, augmented reality (AR) content, and/or mixed reality (MR) content may be provided to users. One challenge with wearable devices is heat management. Operation of electronic (and mechanical) components in such devices generates heat. In addition, some wearable devices such as near-eye display devices and head-mount display devices may also be heated by external sources such as ambient temperature, a wearer's body temperature, and/or sunlight or similar heat sources. Excess heat may cause undesirable operation in some of the electronic components, increase power consumption, and potentially reduce a reliability of parts or all of the wearable device. A side effect of poor thermal management may include that it may reduce user comfort substantially. Another challenge with wearable devices is limited available power and relatively small form meaning available surface for heatsink operations may be limited along with high power consuming active cooling components.

The present disclosure describes an approach for heat management in wearable devices. In some examples, one or more vibration enhanced convection heat transfer surfaces may be incorporated to exterior surfaces of a wearable device. A controller may take into account ambient temperature, available power expected power consumption by the vibration enhanced convection heat transfer surface(s), and/or expected heat reduction, and activate the vibration enhanced convection heat transfer surface(s) to expel heat from the wearable device. Operational parameters of the vibration enhanced convection heat transfer surface(s) such as a frequency and/or an amplitude of vibration may also be determined and set based on the internal and external factors including a shape, a location, and/or a size of the vibration enhanced convection heat transfer surface(s). This may be done actively at all times or on demand to maximize thermal management performance at minimal energy expense.

While some advantages and benefits of the present disclosure are apparent, other advantages and benefits may include increased battery life for a wearable device by reducing power consumption through cooling (e.g., drivers, laser diodes, VCSELs, superluminescent LEDs and any other similar technology operating at lower junction temperatures), increase reliability, and prevention of undesirable operation due to excess heat.

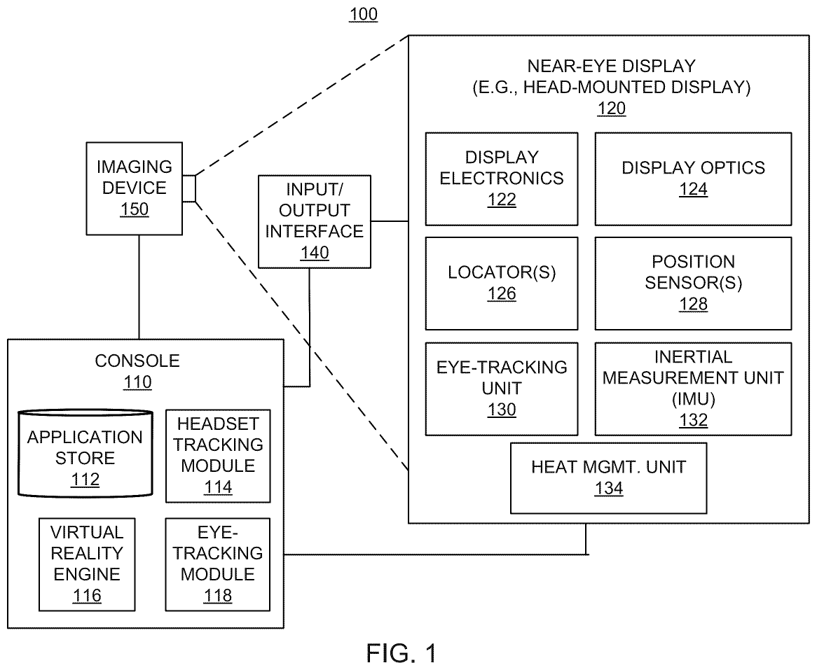

FIG. 1 illustrates a block diagram of an artificial reality system environment 100 including a near-eye display, according to an example. As used herein, a “near-eye display” may refer to a device (e.g., an optical device) that may be in close proximity to a user's eye. As used herein, “artificial reality” may refer to aspects of, among other things, a “metaverse” or an environment of real and virtual elements and may include use of technologies associated with virtual reality (VR), augmented reality (AR), and/or mixed reality (MR). As used herein a “user” may refer to a user or wearer of a “near-eye display.”

As shown in FIG. 1, the artificial reality system environment 100 may include a near-eye display 120, an optional external imaging device 150, and an optional input/output interface 140, each of which may be coupled to a console 110. The console 110 may be optional in some instances as the functions of the console 110 may be integrated into the near-eye display 120. In some examples, the near-eye display 120 may be a head-mounted display (HMD) that presents content to a user.

In some instances, for a near-eye display system, it may generally be desirable to expand an eye box, reduce display haze, improve image quality (e.g., resolution and contrast), reduce physical size, increase power efficiency, and increase or expand field of view (FOV). As used herein, “field of view” (FOV) may refer to an angular range of an image as seen by a user, which is typically measured in degrees as observed by one eye (for a monocular head-mounted display (HMD)) or both eyes (for binocular head-mounted displays (HMDs)). Also, as used herein, an “eye box” may be a two-dimensional box that may be positioned in front of the user's eye from which a displayed image from an image source may be viewed.

In some examples, in a near-eye display system, light from a surrounding environment may traverse a “see-through” region of a waveguide display (e.g., a transparent substrate) to reach a user's eyes. For example, in a near-eye display system, light of projected images may be coupled into a transparent substrate of a waveguide, propagate within the waveguide, and be coupled or directed out of the waveguide at one or more locations to replicate exit pupils and expand the eye box.

In some examples, the near-eye display 120 may include one or more rigid bodies, which may be rigidly or non-rigidly coupled to each other. In some examples, a rigid coupling between rigid bodies may cause the coupled rigid bodies to act as a single rigid entity, while in other examples, a non-rigid coupling between rigid bodies may allow the rigid bodies to move relative to each other.

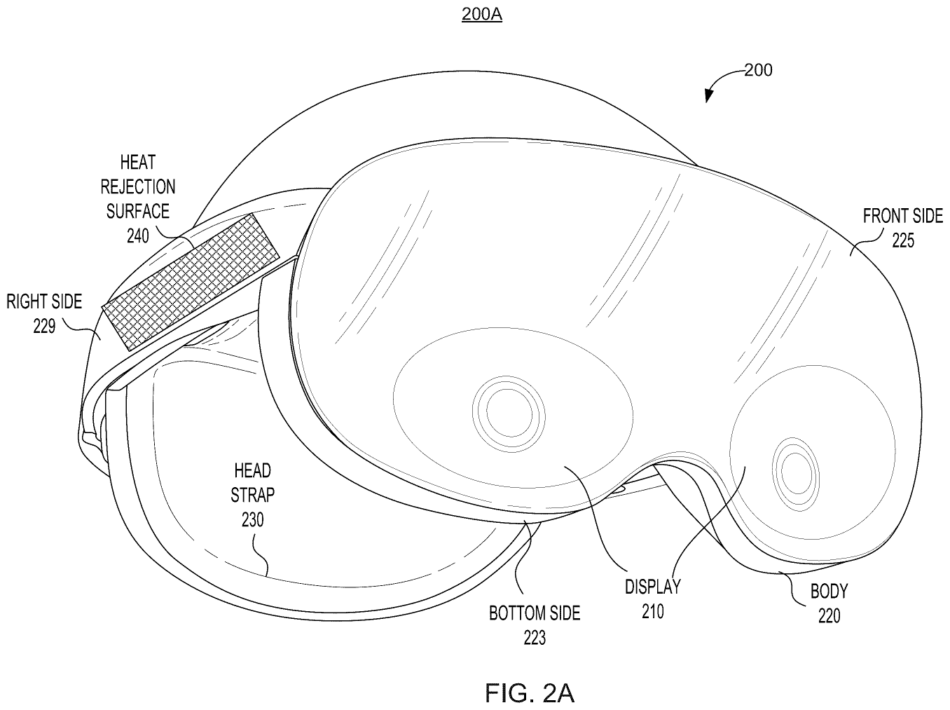

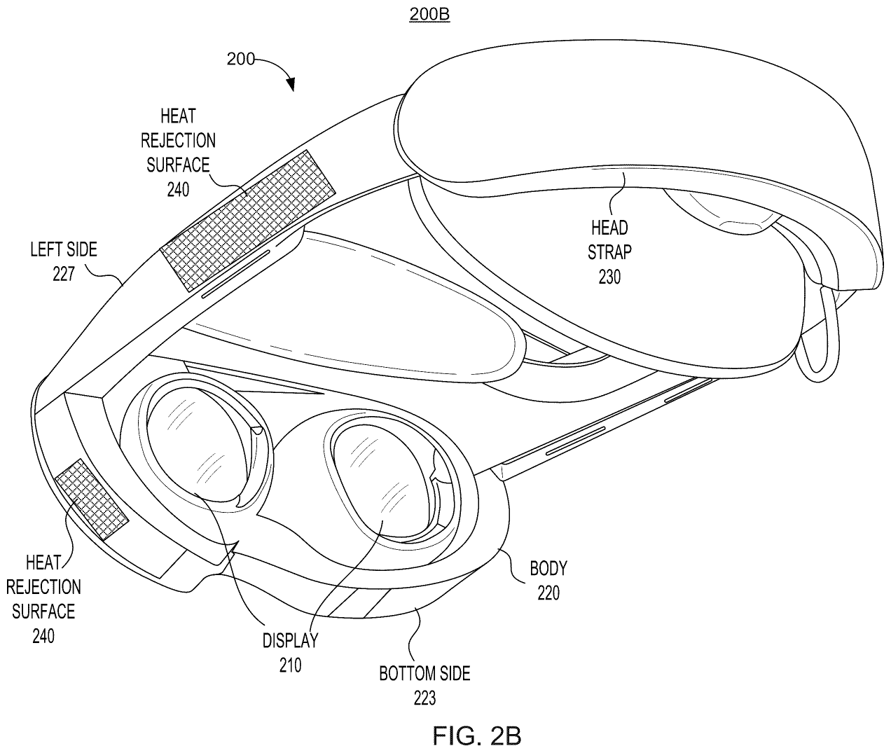

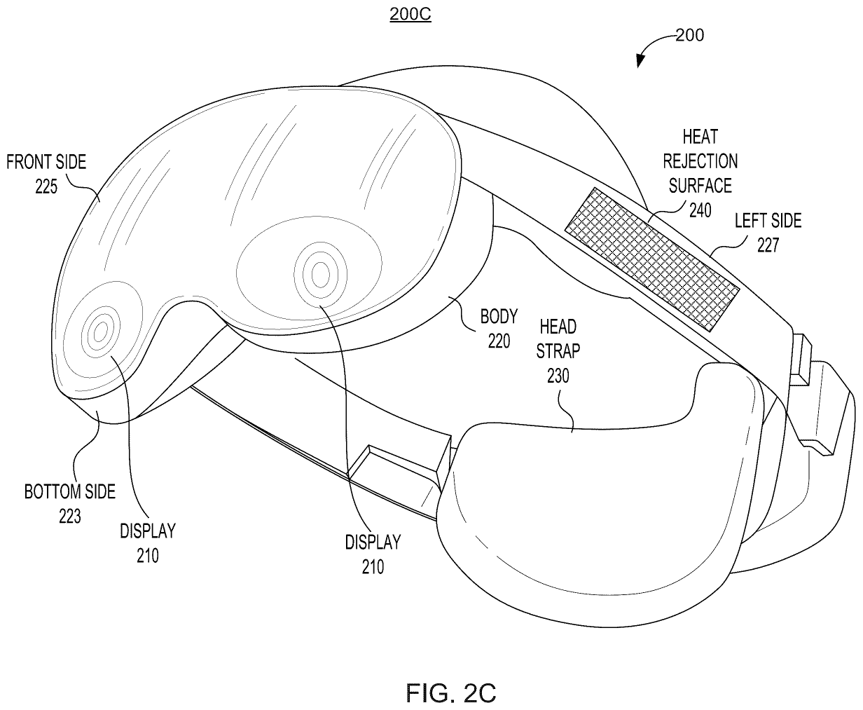

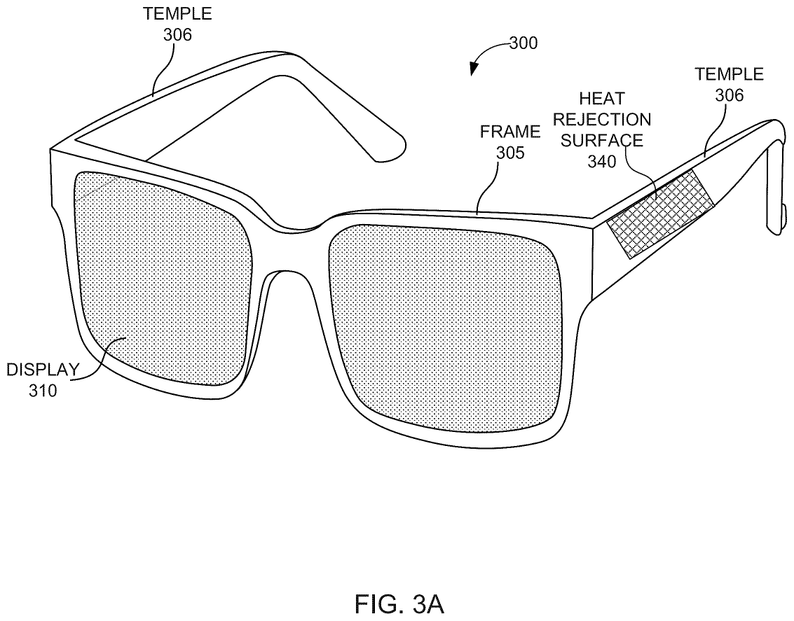

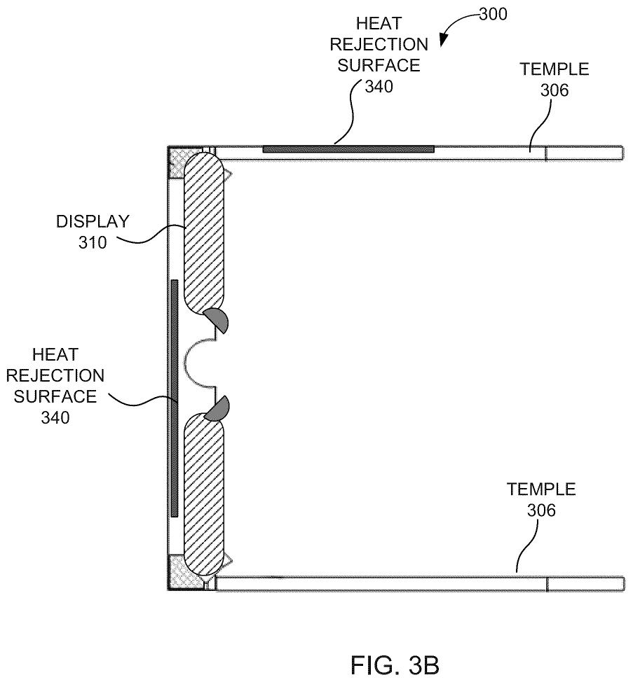

In some examples, the near-eye display 120 may be implemented in any suitable form-factor, including a head-mounted display (HMD), a pair of glasses, or other similar wearable eyewear or device. Examples of the near-eye display 120 are further described below with respect to FIGS. 2 and 3. Additionally, in some examples, the functionality described herein may be used in a head-mounted display (HMD) or headset that may combine images of an environment external to the near-eye display 120 and artificial reality content (e.g., computer-generated images). Therefore, in some examples, the near-eye display 120 may augment images of a physical, real-world environment external to the near-eye display 120 with generated and/or overlaid digital content (e.g., images, video, sound, etc.) to present an augmented reality to a user.

In some examples, the near-eye display device 120 may include a heat management unit 134. The heat management unit 134 may manage activation and operation of one or more heat rejection surfaces on the near-eye display device 120. Convection heat transfer to the surrounding air may be enhanced by the vibrating heat rejection surface(s) that promote air mixing. Vibration parameters (frequency, amplitude) may be tunable pre- or during operation. The heat rejection surface(s) may be smooth or include arbitrary or shaped textures to contribute to the cooling effect, and may be made from a thermal conductor, such as, a metal to facilitate heat transfer. In some examples, surfaces of the near-eye display device 120 may additionally be optimized to maximize radiative heat transfer, in addition to the convection. Coatings and increased surface area by texturing may be employed. The heat management unit 134 may take into account ambient temperature, available power expected power consumption by the vibration enhanced convection heat transfer surface(s), and/or expected heat reduction, and activate the heat rejection surface(s) to expel heat from the near-eye display device 120. Operational parameters of the heat rejection surface(s) such as a frequency and/or an amplitude of vibration may also be determined and set based on the internal and external factors including a shape, a location, and/or a size of each heat rejection surface.

In some examples, the near-eye display 120 may include any number of display electronics 122, display optics 124, and an eye tracking unit 130. In some examples, the near-eye display 120 may also include one or more locators 126, one or more position sensors 128, and an inertial measurement unit (IMU) 132. In some examples, the near-eye display 120 may omit any of the eye tracking unit 130, the one or more locators 126, the one or more position sensors 128, and the inertial measurement unit (IMU) 132, or may include additional elements.

In some examples, the display electronics 122 may display or facilitate the display of images to the user according to data received from, for example, the optional console 110. In some examples, the display electronics 122 may include one or more display panels. In some examples, the display electronics 122 may include any number of pixels to emit light of a predominant color such as red, green, blue, white, or yellow. In some examples, the display electronics 122 may display a three-dimensional (3D) image, e.g., using stereoscopic effects produced by two-dimensional panels, to create a subjective perception of image depth.

In some examples, the near-eye display 120 may include a projector (not shown), which may form an image in angular domain for direct observation by a viewer's eye through a pupil. The projector may employ a controllable light source (e.g., a laser source) and a micro-electromechanical system (MEMS) beam scanner to create a light field from, for example, a collimated light beam. In some examples, the same projector or a different projector may be used to project a fringe pattern on the eye, which may be captured by a camera and analyzed (e.g., by the eye tracking unit 130) to determine a position of the eye (the pupil), a gaze, etc.

In some examples, the display optics 124 may display image content optically (e.g., using optical waveguides and/or couplers) or magnify image light received from the display electronics 122, correct optical errors associated with the image light, and/or present the corrected image light to a user of the near-eye display 120. In some examples, the display optics 124 may include a single optical element or any number of combinations of various optical elements as well as mechanical couplings to maintain relative spacing and orientation of the optical elements in the combination. In some examples, one or more optical elements in the display optics 124 may have an optical coating, such as an anti-reflective coating, a reflective coating, a filtering coating, and/or a combination of different optical coatings.

In some examples, the display optics 124 may also be designed to correct one or more types of optical errors, such as two-dimensional optical errors, three-dimensional optical errors, or any combination thereof. Examples of two-dimensional errors may include barrel distortion, pincushion distortion, longitudinal chromatic aberration, and/or transverse chromatic aberration. Examples of three-dimensional errors may include spherical aberration, chromatic aberration field curvature, and astigmatism.

In some examples, the one or more locators 126 may be objects located in specific positions relative to one another and relative to a reference point on the near-eye display 120. In some examples, the optional console 110 may identify the one or more locators 126 in images captured by the optional external imaging device 150 to determine the artificial reality headset's position, orientation, or both. The one or more locators 126 may each be a light-emitting diode (LED), a corner cube reflector, a reflective marker, a type of light source that contrasts with an environment in which the near-eye display 120 operates, or any combination thereof.

In some examples, the external imaging device 150 may include one or more cameras, one or more video cameras, any other device capable of capturing images including the one or more locators 126, or any combination thereof. The optional external imaging device 150 may be configured to detect light emitted or reflected from the one or more locators 126 in a field of view of the optional external imaging device 150.

In some examples, the one or more position sensors 128 may generate one or more measurement signals in response to motion of the near-eye display 120. Examples of the one or more position sensors 128 may include any number of accelerometers, gyroscopes, magnetometers, and/or other motion-detecting or error-correcting sensors, or any combination thereof.

In some examples, the inertial measurement unit (IMU) 132 may be an electronic device that generates fast calibration data based on measurement signals received from the one or more position sensors 128. The one or more position sensors 128 may be located external to the inertial measurement unit (IMU) 132, internal to the inertial measurement unit (IMU) 132, or any combination thereof. Based on the one or more measurement signals from the one or more position sensors 128, the inertial measurement unit (IMU) 132 may generate fast calibration data indicating an estimated position of the near-eye display 120 that may be relative to an initial position of the near-eye display 120. For example, the inertial measurement unit (IMU) 132 may integrate measurement signals received from accelerometers over time to estimate a velocity vector and integrate the velocity vector over time to determine an estimated position of a reference point on the near-eye display 120. Alternatively, the inertial measurement unit (IMU) 132 may provide the sampled measurement signals to the optional console 110, which may determine the fast calibration data.

In some examples, the near-eye display 120 may use the orientation of the eye to introduce depth cues (e.g., blur image outside of the user's main line of sight), collect heuristics on the user interaction in the virtual reality (VR) media (e.g., time spent on any particular subject, object, or frame as a function of exposed stimuli), some other functions that are based in part on the orientation of at least one of the user's eyes, or any combination thereof. In some examples, because the orientation may be determined for both eyes of the user, the eye tracking unit 130 may be able to determine where the user is looking or predict any user patterns, etc.

In some examples, the input/output interface 140 may be a device that allows a user to send action requests to the optional console 110. As used herein, an “action request” may be a request to perform a particular action. For example, an action request may be to start or to end an application or to perform a particular action within the application. The input/output interface 140 may include one or more input devices. Example input devices may include a keyboard, a mouse, a game controller, a glove, a button, a touch screen, or any other suitable device for receiving action requests and communicating the received action requests to the optional console 110. In some examples, an action request received by the input/output interface 140 may be communicated to the optional console 110, which may perform an action corresponding to the requested action.

In some examples, the optional console 110 may provide content to the near-eye display 120 for presentation to the user in accordance with information received from one or more of external imaging device 150, the near-eye display 120, and the input/output interface 140. For example, in the example shown in FIG. 1, the optional console 110 may include an application store 112, a headset tracking module 114, a virtual reality engine 116, and an eye tracking module 118. Some examples of the optional console 110 may include different or additional modules than those described in conjunction with FIG. 1.

Functions further described below may be distributed among components of the optional console 110 in a different manner than is described here.

In some examples, the optional console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In some examples, the modules of the optional console 110 described in conjunction with FIG. 1 may be encoded as instructions in the non-transitory computer-readable storage medium that, when executed by the processor, cause the processor to perform the functions further described below. It should be appreciated that the optional console 110 may or may not be needed or the optional console 110 may be integrated with or separate from the near-eye display 120.

In some examples, the application store 112 may store one or more applications for execution by the optional console 110. An application may include a group of instructions that, when executed by a processor, generates content for presentation to the user. Examples of the applications may include gaming applications, conferencing applications, video playback application, or other suitable applications.

In some examples, the headset tracking module 114 may track movements of the near-eye display 120 using slow calibration information from the external imaging device 150. For example, the headset tracking module 114 may determine positions of a reference point of the near-eye display 120 using observed locators from the slow calibration information and a model of the near-eye display 120. Additionally, in some examples, the headset tracking module 114 may use portions of the fast calibration information, the slow calibration information, or any combination thereof, to predict a future location of the near-eye display 120. In some examples, the headset tracking module 114 may provide the estimated or predicted future position of the near-eye display 120 to the virtual reality engine 116.

In some examples, the virtual reality engine 116 may execute applications within the artificial reality system environment 100 and receive position information of the near-eye display 120, acceleration information of the near-eye display 120, velocity information of the near-eye display 120, predicted future positions of the near-eye display 120, or any combination thereof from the headset tracking module 114. In some examples, the virtual reality engine 116 may also receive estimated eye position and orientation information from the eye tracking module 118. Based on the received information, the virtual reality engine 116 may determine content to provide to the near-eye display 120 for presentation to the user.

In some examples, the eye tracking module 118, which may be implemented as a processor, may receive eye tracking data from the eye tracking unit 130 and determine the position of the user's eye based on the eye tracking data. In some examples, the position of the eye may include an eye's orientation, location, or both relative to the near-eye display 120 or any element thereof. So, in these examples, because the eye's axes of rotation change as a function of the eye's location in its socket, determining the eye's location in its socket may allow the eye tracking module 118 to more accurately determine the eye's orientation.

In some examples, a location of a projector of a display system may be adjusted to enable any number of design modifications. For example, in some instances, a projector may be located in front of a viewer's eye (i.e., “front-mounted” placement). In a front-mounted placement, in some examples, a projector of a display system may be located away from a user's eyes (i.e., “world-side”). In some examples, a head-mounted display (HMD) device may utilize a front-mounted placement to propagate light towards a user's eye(s) to project an image.

FIGS. 2A-2C illustrate various views of a near-eye display device including at least one heat rejection surface in the form of a head-mounted display (HMD) device, according to examples. In some examples, the head-mounted device (HMD) device 200 may be a part of a virtual reality (VR) system, an augmented reality (AR) system, a mixed reality (MR) system, another system that uses displays or wearables, or any combination thereof. As shown in diagram 200A of FIG. 2A, the head-mounted display (HMD) device 200 may include a body 220 and a head strap 230. The front perspective view of the head-mounted display (HMD) device 200 further shows a bottom side 223, a front side 225, and a right side 229 of the body 220. In some examples, the head strap 230 may have an adjustable or extendible length. In particular, in some examples, there may be a sufficient space between the body 220 and the head strap 230 of the head-mounted display (HMD) device 200 for allowing a user to mount the head-mounted display (HMD) device 200 onto the user's head. For example, the length of the head strap 230 may be adjustable to accommodate a range of user head sizes. In some examples, the head-mounted display (HMD) device 200 may include additional, fewer, and/or different components such as a display 210 to present a wearer augmented reality (AR)/virtual reality (VR) content and a camera to capture images or videos of the wearer's environment.

As shown in the bottom perspective view of diagram 200B of FIG. 2B, the display 210 may include one or more display assemblies and present, to a user (wearer), media or other digital content including virtual and/or augmented views of a physical, real-world environment with computer-generated elements. Examples of the media or digital content presented by the head-mounted display (HMD) device 200 may include images (e.g., two-dimensional (2D) or three-dimensional (3D) images), videos (e.g., 2D or 3D videos), audio, or any combination thereof. In some examples, the user may interact with the presented images or videos through eye tracking sensors enclosed in the body 220 of the head-mounted display (HMD) device 200. The eye tracking sensors may also be used to adjust and improve quality of the presented content. The head-mounted display (HMD) device 200 may also include a heat rejection surface 240 on an outside surface (e.g., right side 229) such that the heat rejection surface 240 can expel heat into the environment through vibration enhancement.

In some examples, the head-mounted display (HMD) device 200 may include various sensors (not shown), such as depth sensors, motion sensors, position sensors, and/or eye tracking sensors. Some of these sensors may use any number of structured or unstructured light patterns for sensing purposes. In some examples, the head-mounted display (HMD) device 200 may include an input/output interface for communicating with a console communicatively coupled to the head-mounted display (HMD) device 200 through wired or wireless means. In some examples, the head-mounted display (HMD) device 200 may include a virtual reality engine (not shown) that may execute applications within the head-mounted display (HMD) device 200 and receive depth information, position information, acceleration information, velocity information, predicted future positions, or any combination thereof of the head-mounted display (HMD) device 200 from the various sensors.

In some examples, the information received by the virtual reality engine may be used for producing a signal (e.g., display instructions) to the display 210. In some examples, the head-mounted display (HMD) device 200 may include locators (not shown), which may be located in fixed positions on the body 220 of the head-mounted display (HMD) device 200 relative to one another and relative to a reference point. Each of the locators may emit light that is detectable by an external imaging device. This may be useful for the purposes of head tracking or other movement/orientation. It should be appreciated that other elements or components may also be used in addition or in lieu of such locators.

FIG. 3A is a perspective view of a near-eye display 300 including at least one heat rejection surface in the form of a pair of glasses (or other similar eyewear), according to an example. In some examples, the near-eye display 300 may be a specific example of near-eye display 120 of FIG. 1 and may be configured to operate as a virtual reality display, an augmented reality (AR) display, and/or a mixed reality (MR) display.

In some examples, the near-eye display 300 may include a frame 305, two temples 306, and a display 310. In some examples, the display 310 may be configured to present media or other content to a user. In some examples, the display 310 may include display electronics and/or display optics, similar to components described with respect to FIGS. 1-2A/2C. For example, as described above with respect to the near-eye display 120 of FIG. 1, the display 310 may include a liquid crystal display (LCD) display panel, a light-emitting diode (LED) display panel, or an optical display panel (e.g., a waveguide display assembly). In some examples, the display 310 may also include any number of optical components, such as waveguides, gratings, lenses, mirrors, etc. In other examples, the display 310 may include a projector, or in place of the display 310 the near-eye display 300 may include a projector.

In some examples, the near-eye display 300 may further include various sensors on or within a frame 305. In some examples, the various sensors may include any number of depth sensors, motion sensors, position sensors, inertial sensors, and/or ambient light sensors, as shown. In some examples, the various sensors may include any number of image sensors configured to generate image data representing different fields of views in one or more different directions. In some examples, the various sensors may be used as input devices to control or influence the displayed content of the near-eye display, and/or to provide an interactive virtual reality (VR), augmented reality (AR), and/or mixed reality (MR) experience to a user of the near-eye display 300. In some examples, the various sensors may also be used for stereoscopic imaging or other similar applications.

In some examples, the near-eye display 300 may further include one or more illuminators to project light into a physical environment. The projected light may be associated with different frequency bands (e.g., visible light, infra-red light, ultra-violet light, etc.), and may serve various purposes. In some examples, the one or more illuminator(s) may be used as locators, such as the one or more locators 126 described above with respect to FIGS. 1-2A/2C.

In some examples, the near-eye display 300 may also include a camera or other image capture unit. The camera, for instance, may capture images of the physical environment in the field of view. In some instances, the captured images may be processed, for example, by a virtual reality engine (e.g., the virtual reality engine 116 of FIG. 1) to add virtual objects to the captured images or modify physical objects in the captured images, and the processed images may be displayed to the user by the display 310 for augmented reality (AR) and/or mixed reality (MR) applications. The near-eye display 300 may also include an eye tracking camera.

In some examples, the near-eye display device 300 may include one or more heat rejection surfaces 340, for example on a surface of temple 306 or frame 305. Convection heat transfer to the surrounding air may be enhanced by the vibrating heat rejection surface(s) that promote air mixing. Vibration parameters (frequency, amplitude) may be tunable pre- or during operation. The heat rejection surface(s) may be smooth or include arbitrary or shaped textures to contribute to the cooling effect, and may be made from a thermal conductor, such as, a metal to facilitate heat transfer. Operational parameters of the heat rejection surface(s) 340 such as a frequency and/or an amplitude of vibration may also be determined and set based on the internal and external factors including a shape, a location, and/or a size of each heat rejection surface.

FIG. 3B is a top view of a near-eye display 300 including at least one heat rejection surface in the form of a pair of glasses (or other similar eyewear), according to an example. In some examples, the near-eye display 300 may include a frame 305 and temples 306 having a form factor of a pair of eyeglasses. The frame 305 supports, for each eye: a fringe projector such as any fringe projector variant considered herein, a display 310 to present content to an eye box, an eye tracking camera, and one or more illuminators. The illuminators may be used for illuminating an eye box, as well as, for providing glint illumination to the eye. The fringe projector may provide a periodic fringe pattern onto a user's eye. The display 310 may include a pupil-replicating waveguide to receive the fan of light beams and provide multiple laterally offset parallel copies of each beam of the fan of light beams, thereby extending a projected image over the eye box.

In some examples, the pupil-replicating waveguide may be transparent or translucent to enable the user to view the outside world together with the images projected into each eye and superimposed with the outside world view. The images projected into each eye may include objects disposed with a simulated parallax, so as to appear immersed into the real-world view.

The eye tracking camera may be used to determine position and/or orientation of both eyes of the user. Once the position and orientation of the user's eyes are known, a gaze convergence distance and direction may be determined. The imagery displayed by the display 310 may be adjusted dynamically to account for the user's gaze, for a better fidelity of immersion of the user into the displayed augmented reality scenery, and/or to provide specific functions of interaction with the augmented reality. In operation, the illuminators may illuminate the eyes at the corresponding eye boxes, to enable the eye tracking cameras to obtain the images of the eyes, as well as to provide reference reflections. The reflections (also referred to as “glints”) may function as reference points in the captured eye image, facilitating the eye gazing direction determination by determining position of the eye pupil images relative to the glints. To avoid distracting the user with illuminating light, the latter may be made invisible to the user. For example, infrared light may be used to illuminate the eye boxes.

In some examples, the image processing and eye position/orientation determination functions may be performed by a central controller, not shown, of the near-eye display 300. The central controller may also provide control signals to the display 310 to generate the images to be displayed to the user, depending on the determined eye positions, eye orientations, gaze directions, eyes vergence, etc. The central controller may also manage operation of the heat rejection surface(s) 340.

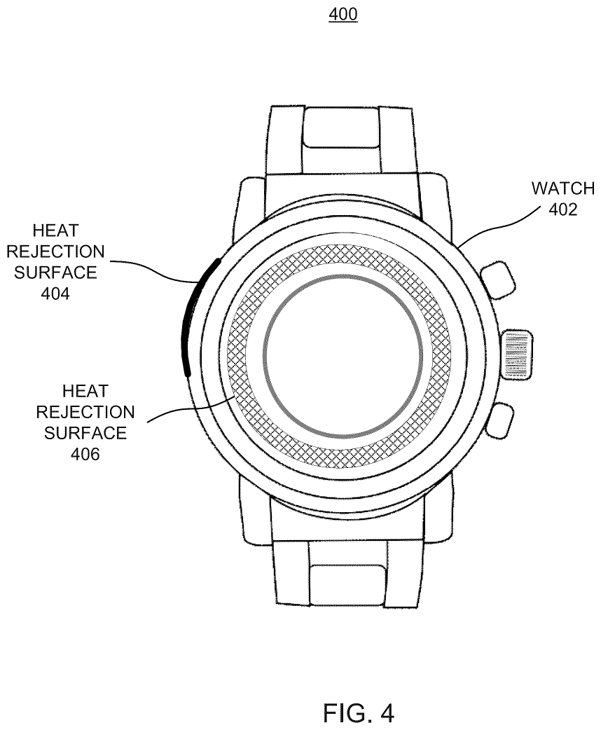

FIG. 4 illustrates a smartwatch with at least one heat rejection surface, according to an example. Diagram 400 shows a smartwatch 402, where one or more heat rejection surfaces may be embedded in the smartwatch 402. For example, heat rejection surface 404 may be on a side surface of the smartwatch 402 while heat rejection surface 406 is positioned on a face surface of the smartwatch 402. The smartwatch 402 may present audio, visual, or other content to a user, enable communication, monitor bodily functions, and perform other functions. Convection heat transfer to the surrounding air may be enhanced by the vibrating heat rejection surface(s) that promote air mixing. Vibration parameters (frequency, amplitude) may be tunable pre- or during operation. The heat rejection surface(s) may be smooth or include arbitrary or shaped textures to contribute to the cooling effect, and may be made from a thermal conductor, such as, a metal to facilitate heat transfer. Operational parameters of the heat rejection surface(s) 404, 406 such as a frequency and/or an amplitude of vibration may also be determined and set based on the internal and external factors including a shape, a location, and/or a size of each heat rejection surface.

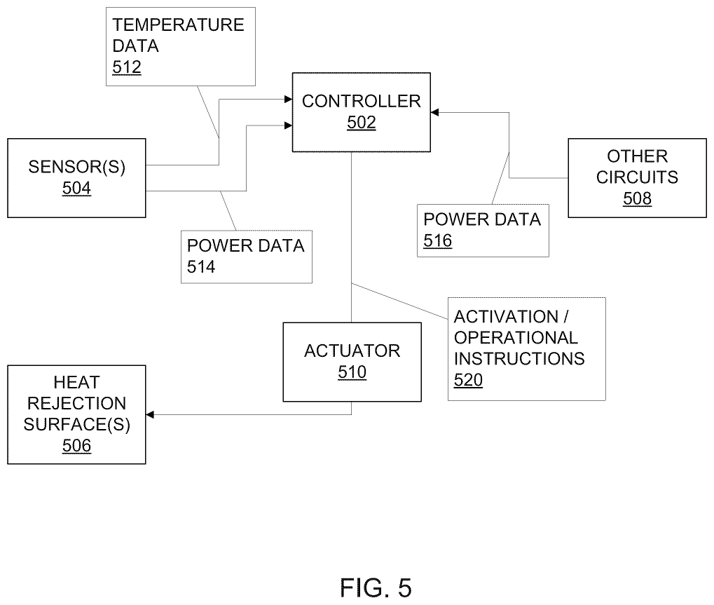

FIG. 5 illustrates a block diagram of major components and their interaction in a wearable device with heat management through vibration enhanced convection heat transfer, according to examples. Diagram 500 includes a controller 502, which may be coupled to one or more sensors 504 and receive information such as temperature data 512, power data 514, etc. The controller may also be coupled to other circuits 508 and receive power data 516 from the other circuits 508. The controller may be further coupled to one or more heat rejection surfaces 506 through an actuator 510 and provide activation and/or operational parameter instructions 520. The actuator 510 may include, but is not limited to, a piezoelectric vibrator, a miniature vibration motor, a micro-electric mechanical system (MEMS) vibration device, etc. More generally, any type of transducer and motion coupling that can produce vibrational motion in the desired frequency and amplitude range may be utilized as actuator.

In some examples, the sensors 504 may provide ambient temperature information, wearer's body temperature information, electronic component temperature information, and similar data to allow the controller 502 to determine if active convection heat transfer is need and at what level. Other sensors 504 may provide power information such as available power from an on-board battery. The controller 502 may also receive power consumption information (power data 516) from the other circuits to determine whether power needed by the vibrating heat rejection surfaces 506 to expel heat is acceptable given available power, other circuits' power consumption and internal/external heat levels.

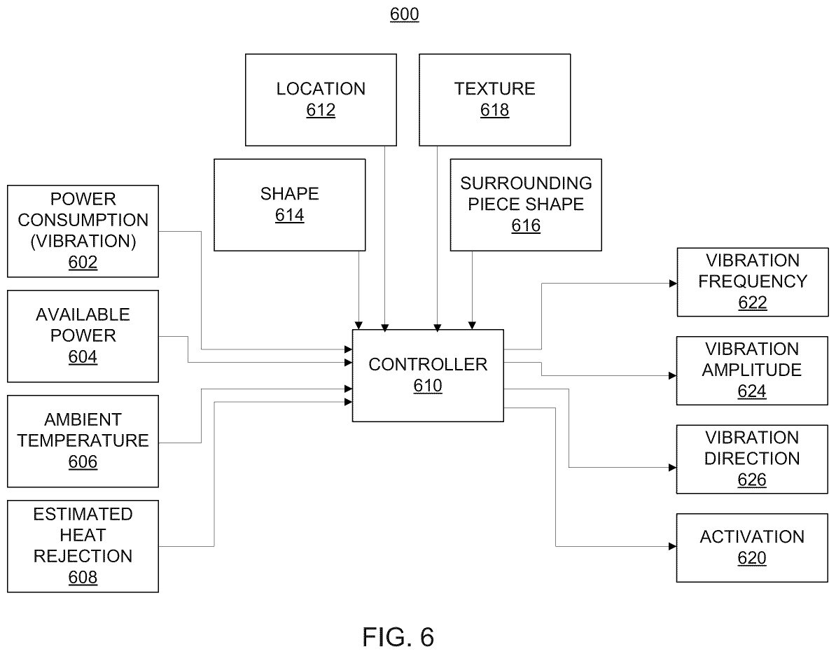

FIG. 6 illustrates various parameters in heat management through vibration enhanced convection heat transfer in a wearable device, according to examples. Diagram 600 shows a controller 610 receiving input information including, but not limited to, power consumption 602 by vibration of heat rejection surfaces, available power 604, ambient temperature 606, estimated heat rejection 608 (based on vibration and/or based on need), shape and size of the heat rejection surfaces 614, location of the heat rejection surfaces 612, texture of the heat rejection surfaces 618, and/or shape of wearable device portion surrounding the heat rejection surfaces 616. The controller 610 may then provide instructions to the heat rejection surfaces with information on vibration frequency 622, vibration amplitude 624, vibration direction 626, and/or activation 620.

In some examples, a mechanism of heat transfer enhancement is via a structured and moving/vibrating heat rejection surface with adjustable frequency and amplitude. The vibration perturbs a thermal boundary layer in a way to promote air mixing and enhances heat exchange between the heat rejection surface and surroundings. With this active cooling approach, heat rejection to the surroundings may be increased by several fold as compared to natural convection under same circumstances. While the vibration enhanced heat transfer may work with smooth surfaces, textured surfaces may further enhance the heat rejection. A direction, an amplitude, and a frequency of the vibration may be tunable parameters depending on other operational conditions of the wearable device such as ambient temperature, electronic components' temperature, available power, power needed for the vibration, etc.

In some examples, the controller 610 may activate the heat rejection surface(s) through an actuator. The actuator may include, but is not limited to, a piezoelectric vibrator, a miniature vibration motor, a micro-electric mechanical system (MEMS) vibration device, etc. More generally, any type of transducer and motion coupling that can produce vibrational motion in the desired frequency and amplitude range may be utilized as actuator. For example, a miniature vibration motor may be as thin as 1.5 mm. A MEMS vibration device (or any of the other types of actuators) may be arranged to modify a direction, amplitude, and/or a frequency of the vibration of the heat rejection surface(s). Direction of actuation can be modified by combining two actuation mechanisms in different directions, by tunable structures, or by other transducer mechanisms.

In some examples, surface texture may be arbitrary and of various length scales. Various three-dimensional (3D) geometries may be designed to amplify the effect. Processes to fabricate the texture may include, but are not limited to, etching (chemical, plasma), machining, 3D printing, sanding, chemical vapor deposition, etc. The heat rejection surface material may be selected from efficient thermal conductors such as metals, as well as ceramics (AlN, SiC, etc.), semiconductors (Si, GaN, etc.) and even high thermal conductivity polymer materials.

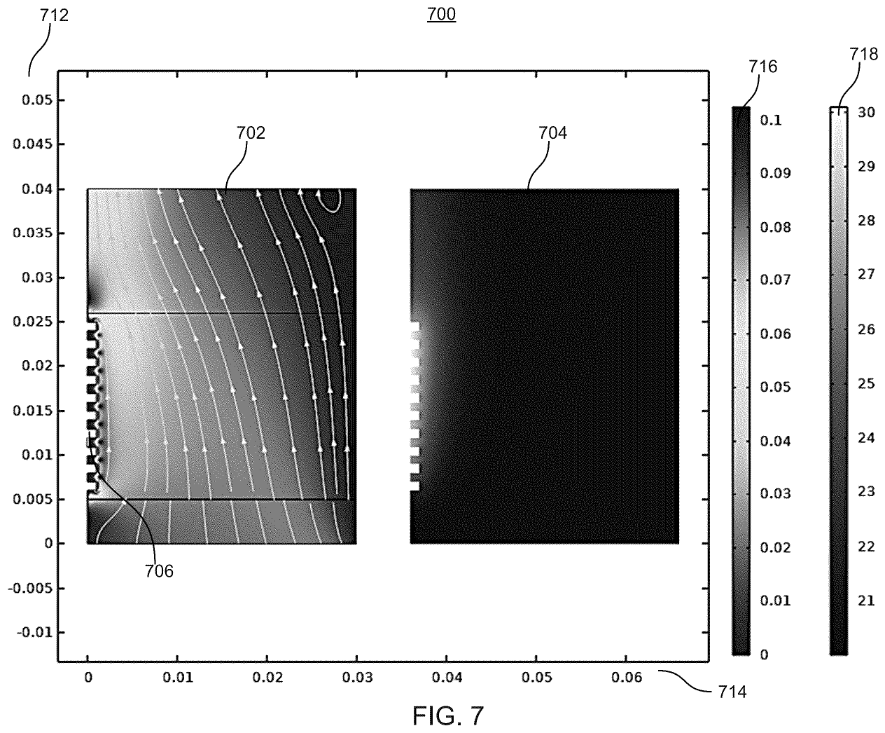

FIG. 7 illustrates heat exchange with the environment for a vibrating heat rejection surface, according to an example. Diagram 700 shows heat exchange simulations between a textured vertical wall 706 (heat rejection surface) and its environment when the vertical wall is vibrating (702) and when it is not vibrating (704). Vertical (712) and horizontal (714) axes represent dimensions. Scale 716 is in m/s and scale 718 is degrees Celsius. The vertical axis 712 is in m.

The example heat rejection surface includes approximately 1 mm high square shaped protrusions as texture. The vibration direction is vertical (the wall moves up and down). Compared to a stationary surface (no vibration) heat transfer of 3.61 Wm⁻²K⁻¹, a vibration at an angular frequency of 1000 rad/s and an amplitude of 0.3 mm may achieve 3.73 Wm⁻²K⁻¹ corresponding to an approximately 3% increase in heat transfer coefficient. With a higher vibration frequency of 3000 rad/s and amplitude of 1 mm, the heat transfer coefficient may reach 16 Wm⁻²K⁻¹ corresponding to approximately 4-fold increase in heat transfer coefficient.

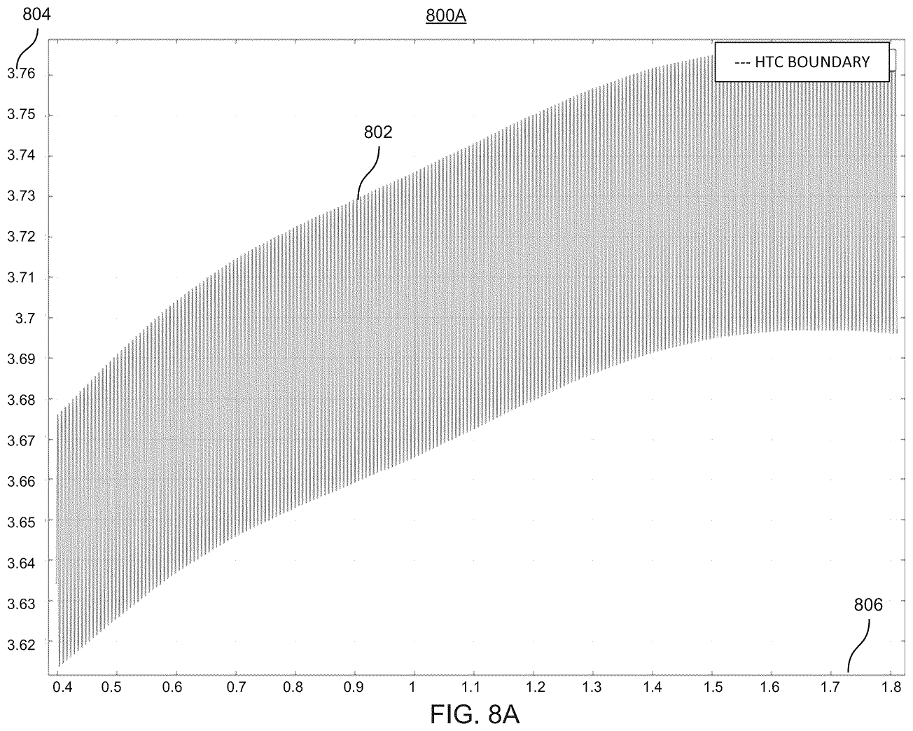

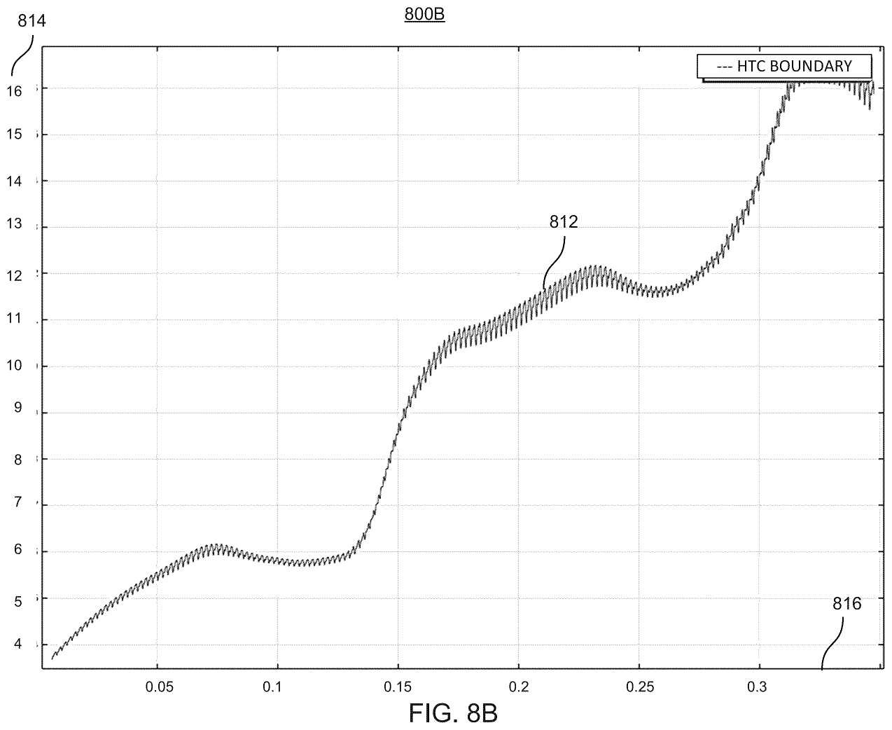

FIGS. 8A and 8B illustrate heat transfer coefficient change for a vibrating heat rejection surface at different vibration frequency and amplitudes, according to examples. Diagram 800A in FIG. 8A shows heat transfer coefficient profile 802, where the vibration frequency and the amplitude vary between steady state (stationary) and 1000 rad/s and 0.3 mm. Vertical axis 804 corresponds to the heat transfer coefficient and horizontal axis 806 corresponds to time in seconds. As can be seen in the heat transfer coefficient profile 802, the heat transfer coefficient changes from approximately 3.62 Wm⁻²K⁻¹ to approximately 3.76 Wm⁻²K⁻¹. The heat transfer coefficient stays at 3.76 Wm⁻²K⁻¹ or higher at times beyond the 1.8 seconds shown in this graph.

Diagram 800B in FIG. 8B shows heat transfer coefficient profile 812, where the vibration frequency and the amplitude vary between steady state (stationary) and 3000 rad/s and 1 mm. Vertical axis 814 corresponds to the heat transfer coefficient and horizontal axis 816 corresponds to time in seconds. As can be seen in the heat transfer coefficient profile 812, the heat transfer coefficient changes from less than 4 Wm⁻²K⁻¹ to approximately 16 Wm⁻²K⁻¹ (a 4-fold increase). The heat transfer coefficient stays at 16 Wm⁻²K⁻¹ or higher at times beyond the 0.35 seconds shown in this graph. Diagram 800A illustrates benefits of a vibration enhanced heat rejection mechanism for a non-optimized vibration scenario. Diagram 800B, on the other hand, shows that a different vibration amplitude and frequency may enhance heat transfer coefficient substantially.

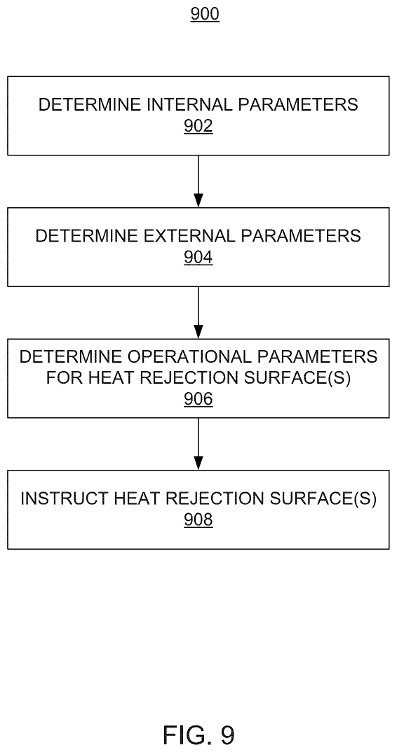

FIG. 9 illustrates a flow diagram for a method of providing heat rejection through vibration enhanced convection heat transfer in a wearable device, according to some examples. The method 900 is provided by way of example, as there may be a variety of ways to carry out the method described herein. Although the method 900 is primarily described as being performed by the components of FIG. 5, the method 900 may be executed or otherwise performed by one or more processing components of another system or a combination of systems. Each block shown in FIG. 9 may further represent one or more processes, methods, or subroutines, and one or more of the blocks may include machine readable instructions stored on a non-transitory computer readable medium and executed by a processor or other type of processing circuit to perform one or more operations described herein. In some examples, an artificial intelligence (AI) element may be employed in conjunction with the controller to enable the predictive thermal management based upon Al-powered deep learning.

At block 902, a controller may receive information from sensors and other circuits within the wearable device or external devices associated with internal parameters such as ambient temperature information, wearer's body temperature information, electronic component temperature information, power information such as available power from an on-board battery, and similar data to allow the controller to determine if active convection heat transfer is needed and at what level.

At block 904, the controller may receive information from other circuits in the wearable device associated with current power consumption by other circuits in the wearable device.

At block 906, the controller may determine operational parameters for the heat rejection surfaces such as direction of vibration, frequency of vibration, amplitude of vibration, and/or duration of vibration. At block 908, the controller may instruct the heat rejection surface(s) to activate based on the determined operational parameters.

According to examples, a method of making a wearable device with vibrating heat rejection surface(s) is described herein. A system of making a wearable device with vibrating heat rejection surface(s) is also described herein. A non-transitory computer-readable storage medium may have an executable stored thereon, which when executed instructs a processor to perform the methods described herein.

In the foregoing description, various examples are described, including devices, systems, methods, and the like. For the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples.

The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example’ is not necessarily to be construed as preferred or advantageous over other embodiments or designs.

Although the methods and systems as described herein may be directed mainly to digital content, such as videos or interactive media, it should be appreciated that the methods and systems as described herein may be used for other types of content or scenarios as well. Other applications or uses of the methods and systems as described herein may also include social networking, marketing, content-based recommendation engines, and/or other types of knowledge or data-driven systems.

1. A heat management system for a wearable device, the system comprising:
at least one heat rejection surface to expel heat from the wearable device through vibration enhanced convection heat transfer; and
a controller coupled to the at least one heat rejection surface, the controller to:
determine at least one internal parameter and external parameter associated with the wearable device;
determine at least one operational parameter for the at least one heat rejection surface based on the at least one internal parameter and external parameter; and
activate the at least one heat rejection surface using the at least one operational parameter.

2. The heat management system of claim 1, wherein activation of the at least one heat rejection surface causes the at least one heat rejection surface to vibrate.

3. The heat management system of claim 1, wherein the at least one internal parameter comprises at least one of an electronic component temperature, a power consumption level, or an available power from an on-board battery of the wearable device.

4. The heat management system of claim 1, wherein the at least one external parameter comprises at least one of an ambient temperature or a wearer's body temperature.

5. The heat management system of claim 1, wherein the at least one operational parameter comprises at least one of a direction of vibration, a frequency of the vibration, an amplitude of the vibration, or a duration of the vibration.

6. The heat management system of claim 1, wherein the at least one heat rejection surface comprises a texture.

7. The heat management system of claim 6, wherein the texture comprises a plurality of three-dimensional shapes.

8. The heat management system of claim 1, wherein the controller is to determine the at least one operational parameter further based on at least one of a shape of the at least one heat rejection surface, a size of the at least one heat rejection surface, a location of the at least one heat rejection surface on the wearable device, a texture of the at least one heat rejection surface, or a shape of a portion of the wearable device surrounding the at least one heat rejection surface.

9. The heat management system of claim 1, wherein the at least one heat rejection surface comprises a thermal conductor.

10. An augmented reality (AR)/virtual reality (VR) wearable device, comprising:
a frame comprising a display;
two temples coupled to the frame; and
a heat management system comprising:
at least one heat rejection surface positioned on an outward-facing surface of at least one of the two temples or the frame, the at least one heat rejection surface to expel heat from the wearable device through vibration enhanced convection heat transfer; and
a controller coupled to the at least one heat rejection surface, the controller to:
determine at least one internal parameter and external parameter associated with the wearable device;
determine at least one operational parameter for the at least one heat rejection surface based on the at least one internal parameter and external parameter; and
cause the at least one heat rejection surface to vibrate using the at least one operational parameter.

11. The AR/VR wearable device of claim 10, wherein
the at least one internal parameter comprises at least one of an electronic component temperature, a power consumption level, or an available power from an on-board battery of the AR/VR wearable device; and
the at least one external parameter comprises at least one of an ambient temperature or a wearer's body temperature.

12. The AR/VR wearable device of claim 10, wherein the at least one operational parameter comprises at least one of a direction of vibration, a frequency of the vibration, an amplitude of the vibration, or a duration of the vibration.

13. The AR/VR wearable device of claim 12, wherein
the direction of vibration comprises vertical or horizontal vibration,
or vibration along any direction between vertical and horizontal,
the frequency of the vibration is at least 200 rad/s, and
the amplitude of the vibration is at least 0.1 mm.

14. The AR/VR wearable device of claim 10, wherein the controller is to determine the at least one operational parameter further based on at least one of a shape of the at least one heat rejection surface, a size of the at least one heat rejection surface, a location of the at least one heat rejection surface on the wearable device, a texture of the at least one heat rejection surface, or a shape of a portion of the AR/VR wearable device surrounding the at least one heat rejection surface.

15. The AR/VR wearable device of claim 10, wherein the at least one heat rejection surface comprises a texture comprising a plurality of arbitrary three-dimensional shapes.

16. The AR/VR wearable device of claim 15, wherein the texture is fabricated through chemical etching, plasma etching, machining, three-dimensional printing, or sanding.

17. The AR/VR wearable device of claim 10, wherein the at least one heat rejection surface comprises a thermal conductor metal.

18. A method, comprising:
receiving, at a controller, information associated with at least one internal parameter and external parameter associated with an augmented reality (AR)/virtual reality (VR) wearable device from at least one sensor;
determining at least one operational parameter for an at least one heat rejection surface based on the at least one internal parameter and external parameter, wherein the at least one heat rejection surface is to expel heat from the wearable device through vibration enhanced convection heat transfer; and
causing the at least one heat rejection surface to vibrate using the at least one operational parameter.

19. The method of claim 18, wherein
the at least one internal parameter comprises at least one of an electronic component temperature, a power consumption level, or an available power from an on-board battery of the AR/VR wearable device; and
the at least one external parameter comprises at least one of an ambient temperature or a wearer's body temperature.

20. The method of claim 18, further comprising:
determining the at least one operational parameter further based on at least one of a shape of the at least one heat rejection surface, a size of the at least one heat rejection surface, a location of the at least one heat rejection surface on the wearable device, a texture of the at least one heat rejection surface, or a shape of a portion of the AR/VR wearable device surrounding the at least one heat rejection surface.
